(19) United States
(12) Patent Application Publication
(10) Pub. No.: US 2015/0083188 A1
(43) Pub. Date: Mar. 26, 2015

(54) SOLAR CELL MODULE AND SOLAR CELL MODULE MANUFACTURING METHOD

(71) Applicant: SANYO Electric Co., Ltd., Osaka (JP)

(72) Inventor: Masahiro IWATA, Osaka (JP)

(21) Appl. No.: 14/560,269

(22) Filed: Dec. 4, 2014

Related U.S. Application Data
(63) Continuation of application No. PCT/JP2012/066771, filed on Jun. 29, 2012.

(51) Int. Cl. H01L 31/0224; H01L 31/02

(52) U.S. Cl. CPC H01L 31/022433; H01L 31/02021
USPC 136/244; 438/66

(57) ABSTRACT

This solar cell module is provided with a plurality of solar cells, and connecting members that connect the solar cells to each other. The area of each of the bonding layers that bonds each of the connecting members to the light receiving surface of each of the solar cells is larger than the area of each of the bonding layers that bonds each of the connecting members to the rear surface of each of the solar cells.

### CROSS-REFERENCE TO RELATED APPLICATIONS

The present application is a continuation under 35 U.S U.S.C. §120 of PCT/JP2012/066771, filed Jun. 29, 2012, which is incorporated herein by reference.

### TECHNICAL FIELD

The present invention relates to a solar cell module and a method of manufacturing a solar cell module.

### BACKGROUND ART

As shown in FIG. 10, a solar cell module 100 has a structure in which collecting electrodes 12 provided for a plurality of solar battery cells 10 are connected to each other by connection members 14. The connection member 14 is adhered to be in electrical conduct with the collecting electrode 12 by a conductive adhesive film in which conductive particles are dispersed.

During thermocompression of the connection member 14, a heating process of about 200° C. is employed. Therefore, when the solar battery cell 10 is cooled after the thermocompression, a contraction force due to thermal contraction of the connection member 14 would be applied on a light receiving surface and a back surface of the solar battery cell 10.

Meanwhile, on the side of the back surface of the solar battery cell 10, the incidence of light does not need to be considered. Thus, in many cases, a placement area of the collecting electrode 12 is set to be larger compared to the side of the light receiving surface, and the adhesion area between the connection member 14 and the collecting electrode 12 is also larger on the back surface side than the light receiving surface side. In addition, the contraction force applied on the light receiving surface and the back surface of the solar battery cell 10 depends on an adhesion force; that is, an adhesion area, between the connection member 14 and the collecting electrode 12. Therefore, when the amounts of adhesives between the connection member 14 and the collecting electrode 12 are the same on the light receiving surface side and the back surface side, the contraction force applied to the solar battery cell 10 would be greater for the back surface side having the larger adhesion area, and, as shown in FIG. 11, curling and cracks may occur in the solar battery cell 10.

Moreover, the curling and the cracks may occur in the solar battery cell 10 from the difference itself in the placement areas of the collecting electrodes 12 provided over the light receiving surface and the back surface of the solar battery cell 10. Specifically, a stronger contraction force would be applied on a side having a larger placement area of the collecting electrode 12 on the light receiving surface or the back surface, and the curling and the cracks may be caused in the solar battery cell 10. In the future, as the thickness of the solar battery cell 10 is reduced, this problem will become more and more significant.

### SUMMARY OF THE INVENTION

According to one aspect of the present invention, there is provided a solar cell module comprising: a plurality of solar cells; and a connection member that connects the plurality of solar cells, wherein an area of an adhesive layer that adheres the connection member over a light receiving surface of the solar cell is larger than an area of an adhesive layer that adheres the connection member over a back surface of the solar cell.

According to another aspect of the present invention, there is provided a method of manufacturing a solar cell module, comprising: a first step in which a connection member is adhered over a light receiving surface of a solar cell with an adhesive layer therebetween; and a second step in which a connection member is adhered over a back surface of the solar cell with an adhesive layer therebetween such that an area of the adhesive layer that adheres the connection member over the light receiving surface of the solar cell is larger than an area of the adhesive layer that adheres the connection member over the back surface of the solar cell.

### BRIEF DESCRIPTION OF DRAWINGS

FIG. 1 is a plan view showing a light receiving surface of a solar cell module according to a preferred embodiment of the present invention.

FIG. 2 is a plan view showing a back surface of a solar cell module according to the preferred embodiment of the present invention.

FIG. 3 is across sectional diagram showing a solar cell module according to the preferred embodiment of the present invention.

FIG. 4 is a plan view showing an adhesive layer over a light receiving surface in the preferred embodiment of the present invention.

FIG. 5 is a plan view showing an adhesive layer over a back surface in the preferred embodiment of the present invention.

FIG. 6 is a diagram for explaining an operation of the solar cell module according to the preferred embodiment of the present invention.

FIG. 7 is a cross sectional diagram showing a joining member over a surface of which an unevenness is provided.

FIG. 8 is a plan view showing an adhesive layer according to the preferred embodiment of the present invention.

FIG. 9 is a diagram for explaining an operation of a solar cell module according to the preferred embodiment of the present invention.

FIG. 10 is a plan view showing a solar cell module of related art.

FIG. 11 is a diagram for explaining curling which occurs in a solar cell module of related art.

### DESCRIPTION OF THE PREFERRED EMBODIMENTS

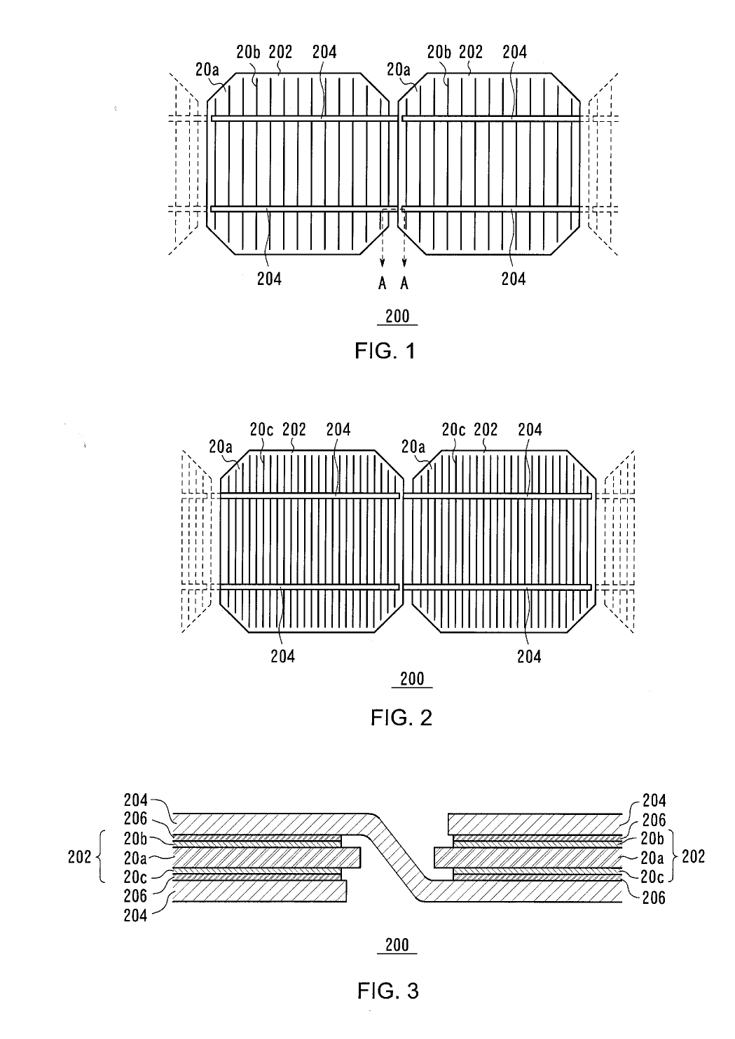

As shown in plan views of FIGS. 1 and 2 and a cross sectional diagram. of FIG. 3, a solar cell module 200 according to a preferred embodiment of the present invention includes a solar battery cell 202, a connection member 204, and an adhesive layer 206. FIG. 1 is a plan view of the solar cell module 200 viewed from the light receiving surface side, and FIG. 2 is a plan view of the solar cell module 200 viewed from the back surface side. FIG. 3 is a cross sectional diagram along an A-A line in FIG. 1.

A “light receiving surface” refers to a primary surface of the solar battery cell 202, and is a surface through which the light from the outside primarily enters the solar cell. For example, 50%˜100% of the light entering the solar battery cell 202 enters from the side of the light receiving surface. A “back surface” refers to another primary surface of the solar battery cell 202, and is a surface on a side opposite from the light receiving surface. The solar battery cell 202 includes a photoelectric conversion unit 20a that receives light such as solar light and produces carriers (electrons and holes), a first electrode 20b provided over the light receiving surface of the photoelectric conversion unit 20a, and a second electrode 20c provided over the back surface of the photoelectric conversion unit 20a. As shown in FIGS. 1 and 2, the first electrode 20b and the second electrode 20c are collecting electrodes having fingers provided in a comb shape to intersect a direction of extension of the connection member 204, and bus bars connecting the fingers. The finger is a narrow line-shaped electrode that collects electric power from the photoelectric conversion unit 20a. The bus bars are electrodes that connect a plurality of the fingers, and are placed in parallel to each other with a predetermined gap therebetween and in a manner to be covered by the connection member 204. The fingers and bus bars are formed, for example, by screen printing in a desired pattern over a transparent conductive layer a conductive paste in which a conductive filler such as silver (Ag) is dispersed in a binder resin. In the solar battery cell 202, the carriers produced at the photoelectric conversion unit 20a are collected by the first electrode 20b and the second electrode 20c.

In the solar battery cell 202, because the amount of incidence of light is lower on the back surface than on the light receiving surface, the second electrode 20c over the back surface is formed having a larger area than the first electrode 20b over the light receiving surface. For example, a greater number of fingers are provided in the first electrode 20b than in the second electrode 20c. Alternatively, when there is no incidence of light from the back surface side of the solar battery cell 202, a metal film such as a silver (Ag) thin film may be formed over substantially the entire surface of the back surface of the photoelectric conversion unit 20a, to form the second electrode 20c.

The photoelectric conversion unit 20a has a substrate made of a semiconductor material such as, for example, crystalline silicon, gallium arsenide (GaAs), indium phosphide (InP), or the like. A structure of the photoelectric conversion unit 20a is not particularly limited, and in the present embodiment, the photoelectric conversion unit 20a has a structure having a hetero junction of an n-type monocrystalline silicon substrate and amorphous silicon. In the photoelectric conversion unit 20a, for example, over the light receiving surface of the n-type monocrystalline silicon substrate, an i-type amorphous silicon layer, a p-type amorphous silicon layer doped with boron (B) or the like, and a transparent conductive layer made of a transparent conductive oxide such as indium oxide, are layered in that order. In addition, over the back surface of the substrate, an i-type amorphous silicon layer, an n-type amorphous silicon layer doped with phosphorus (P) or the like, and a transparent conductive layer are layered in that order.

In the solar cell module 200, adjacent solar battery cells 202 are connected by the connection member 204. As the connection member 204, for example, a metal foil of copper or the like may be employed. The connection member 204 connects the first electrode 20b of a solar battery cell 202 and a second electrode 20c of an adjacent solar battery cell 202. The connection member 204 is adhered to, for example, a bus bar and a finger of the first electrode 20b of one solar battery cell 202 and a bus bar and a finger of the second electrode 20c of the other solar battery cell 202, by the adhesive layer 206.

The adhesive layer 206 may be, for example, a conductive adhesion film or a conductive adhesion paste in which conductive particles are dispersed in a thermosetting resin material having an adhering characteristic such as an epoxy resin, an acrylic resin, a urethane resin, or the like. The conductive adhesion film may be an anisotropic conductive adhesive having a high conductivity in an in-plane direction and a low conductivity in a thickness direction of the solar battery cell 202. Alternatively, there may be employed a non-conductive adhesive paste which does not contain the conductive particles in the thermosetting resin material having an adhering characteristic such as the epoxy resin, the acrylic resin, and the urethane resin.

The connection member 204 has a bent portion in which a step is provided corresponding to the thickness of the solar battery cell 202. The bent portion is provided to form a structural clearance corresponding to the thickness of the solar battery cell 202 for connecting the first electrode 20b and the second electrode 20c to place the adjacent solar battery cells 202 on the same plane.

The solar cell module 200 maybe sealed by a protection member (not shown) for protecting the light receiving surface and the back surface of the solar battery cell 202. For the protection member, a member having a light transmitting characteristic such as, for example, a glass plate, a resin plate, a resin film, or the like maybe employed. The protection member provided on the side of the light receiving surface of the solar battery cell 202 is preferably a transparent member that transmits light of a wavelength band used for the photoelectric conversion at the solar battery cell 202. When there is no incidence of light from the back surface side of the solar battery cell 202, the protection member provided over the back surface side may be a non-transparent plate or film. In this case, as the protection member, for example, a layered film such as a resin film having therein an aluminum foil or the like, may be employed. The protection members are adhered to the light receiving surface and the back surface of the solar battery cell 202 using fillers.

In the solar cell module 200 in the present embodiment, the area of the adhesive layer 206 for adhering the connection member 204 is set different between the light receiving surface and the back surface. Specifically, the area of the adhesive layer 206 of the surface having the smaller placement area between the first electrode 20b of the light receiving surface and the second electrode 20c of the back surface is set to be larger. In other words, when the placement area of the first electrode 20b over the light receiving surface is set smaller than the placement area of the second electrode 20c over the back surface, the area of the adhesive layer 206 used for adhering the connection member 204 over the light receiving surface is set larger than the area of the adhesive layer 206 used for adhering the connection member 204 over the back surface.

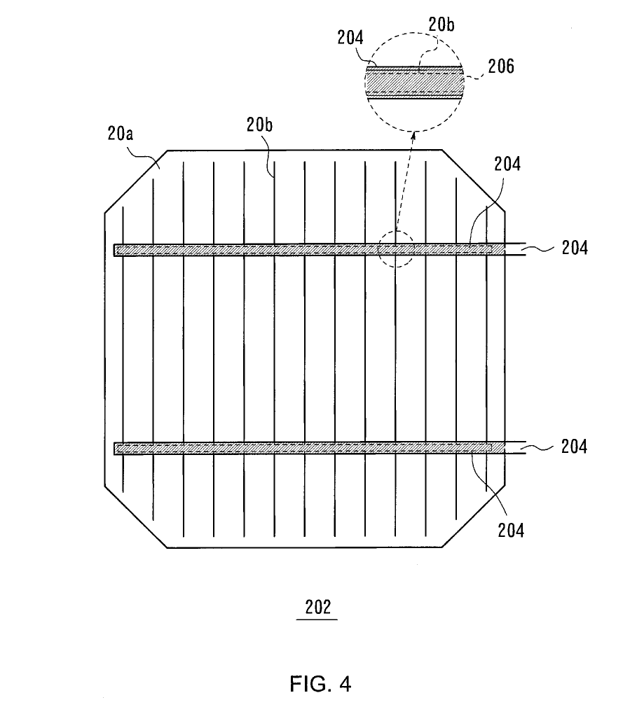

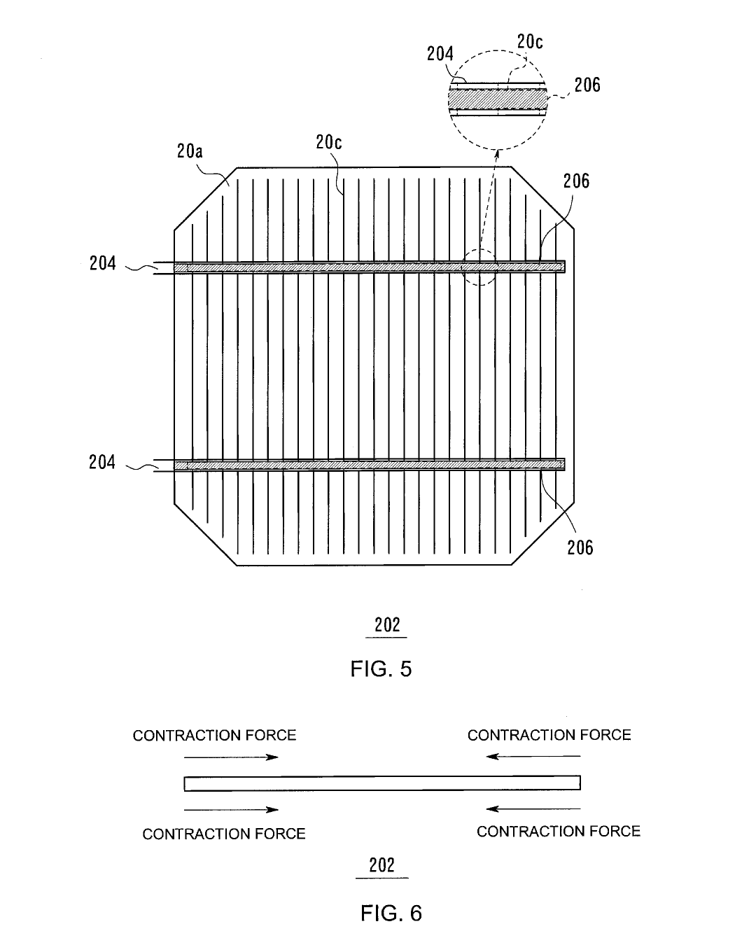

For example, when the connection member 204 is adhered on the light receiving surface side, as shown by hatching in FIG. 4, the adhesive layer 206 is applied over the entire surface of the connection member 204. On the other hand, when the connection member 204 is adhered on the back surface side, as shown by hatching in FIG. 5, an application width of the adhesive layer 206 may be narrowed, and the adhesive layer 206 may be provided on only a part of the connection member 204.

In this process, the areas of the adhesive layers 206 are set such that the contraction force due to the connection member 204 adhered by the adhesion layer 206 is approximately equal between the light receiving surface and the back surface. For example, the areas of the adhesive layers 206 are preferably set such that an adhesion area between the connection member 204 and the first electrode 20b over the light receiving surface is approximately equal to an adhesion area between the connection member 204 and the second electrode 20c over the back surface. In addition, the areas of the adhesive layers 206 are preferably set such that the connection members 204 do not peel off from the solar battery cell 202.

Here, the area of the adhesive layer and the placement area of the electrode refer to the areas occupied by the adhesive layer and the electrode when the solar battery cell 202 is viewed in a plan view from the light receiving surface side or the back surface side as in the plan views of FIGS. 1, 2, 4, and 5.

The contraction forces applied to the light receiving surface and the back surface of the solar battery cell 202 depend on the adhesion forces between the connection member 204 and the first electrode 20b and the second electrode 20c; that is, adhesion areas between the connection member 204 and the first electrode 20b and the second electrode 20c, and the area of the adhesive layer. In the present embodiment, the adhesion area between the connection member 204 and the first electrode 20b is set smaller than the adhesion area between the connection member 204 and the second electrode 20c, and the area of the adhesive layer between the connection member 204 and the first electrode 20b is set larger than the area of the adhesive layer between the connection member 204 and the second electrode 20c. Therefore, as shown by a side view of the solar battery cell 202 of FIG. 6, the contraction forces applied to the light receiving surface and the back surface of the solar battery cell 202 become more uniform, and, consequently, the curling and the cracks of the solar battery cell 202 can be inhibited.

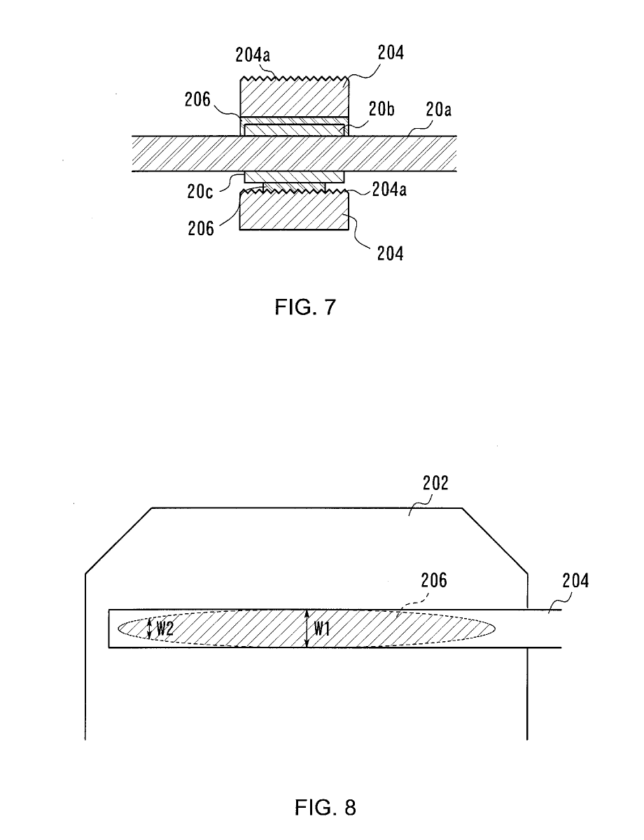

Alternatively, as shown in FIG. 7, an unevenness 204a may be provided over one surface of the connection member 204. By providing such unevenness 204a over one surface of the connection member 204, it becomes possible to achieve a diffusion reflection of the light entering the unevenness 204a, a further reflection by a glass member or the like covering the surface of the connection member 204, and to then introduce the light into the solar battery cell 202. Therefore, the usage efficiency of light in the solar cell module 200 can be improved. The unevenness 204a is preferably provided to be oriented toward the light receiving surface.

In this configuration, even when the unevenness 204a is provided over one surface of the connection member 204, the areas of the adhesive layers 206 may be set such that the contraction forces of the light receiving surface and the back surface by the connection member 204 to be adhered by the adhesive layer 206 are approximately equal to each other. In this manner, the contraction force due to the adhesion is balanced between the light receiving surface and the back surface, and the curling and the cracks of the solar battery cell 202 can be inhibited.

As the contraction force differs between a center part and a part near the end of the solar battery cell 202, alternatively, the area of the adhesive layer 206 per unit area of the solar battery cell 202 may be set to vary along the longitudinal direction of the adhesive layer 206. For example, a width of the adhesive layer 206 is set to vary along the longitudinal direction of the connection member 204. As shown in the plan view of the connection member 204 of FIG. 8, a region having a width W2 of the adhesive layer 206 narrower than a width W1 near the center of the solar battery cell 202 may be provided near the end. By adjusting the area of the adhesive layer 206 in this manner, the contraction force applied to the solar battery cell 202 can be finely adjusted, and the contraction forces applied to the light receiving surface and the back surface of the solar battery cell 202 can be made more uniform. Therefore, a more significant advantage of inhibiting the curling and the cracks of the solar battery cell 202 can be achieved.

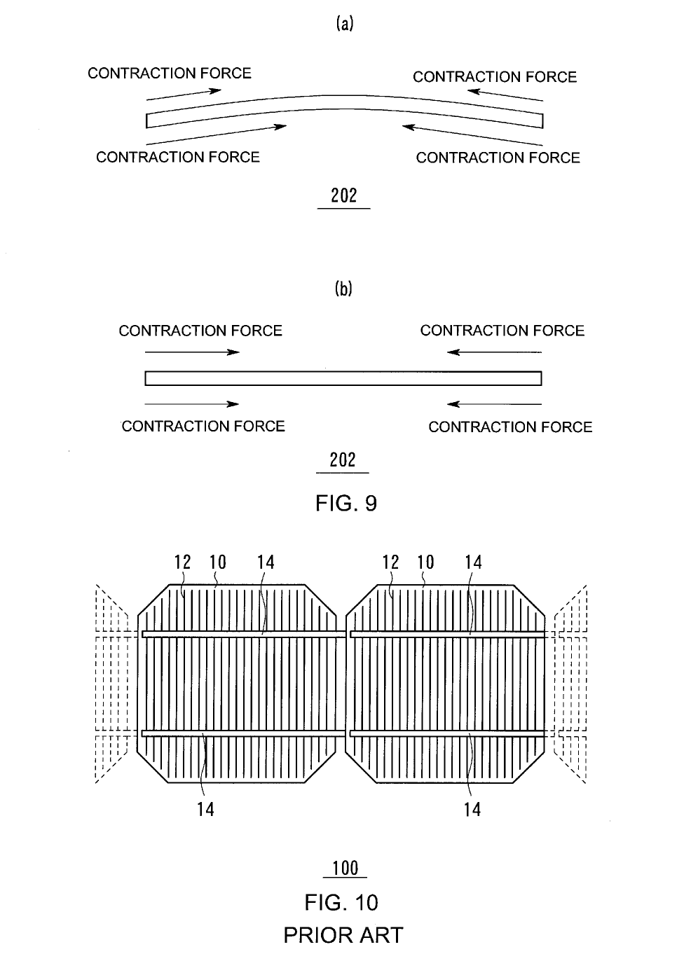

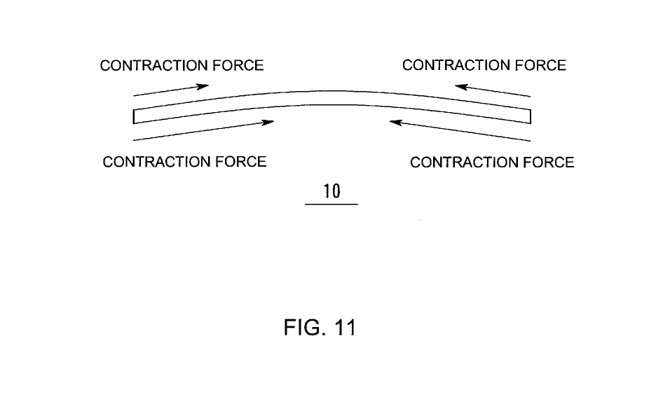

Alternatively, the curling and the cracks of the solar battery cell 202 caused by a difference in the placement areas of the first electrode 20b and the second electrode 20c provided over the light receiving surface and the back surface of the solar battery cell 202 can be reduced. For example, when the placement area of the second electrode 20c over the back surface is larger than the placement area of the first electrode 20b over the light receiving surface, as shown in FIG. 9(a), the solar battery cell 202 may curl in a convex manner in the light receiving surface side. However, by adjusting the area of the adhesive layer 206 for adhering the connection member 204, as shown in FIG. 9(b), the curling of the solar battery cell 202 can be actively resolved. In particular, as the thickness of the solar battery cell 10 is reduced, the advantage of the prevention of the curling becomes more and more significant.

As described, according to the solar cell module 200 of the present embodiment, generation of curling, cracks, or the like of the solar battery cell 202 can be inhibited and reliability of the solar cell module 200 can be improved.

1. A solar cell module comprising:
a plurality of solar cells; and
a connection member that connects the plurality of solar cells, wherein
an area of an adhesive layer that adheres the connection member over a light receiving surface of the solar cell is larger than an area of an adhesive layer that adheres the connection member over a back surface of the solar cell.

2. The solar cell module according to claim 1, wherein
a placement area of a collecting electrode provided over the light receiving surface of the solar cell is smaller than a placement area of a collecting electrode provided over the back surface of the solar cell.

3. The solar cell module according to claim 1, wherein
the adhesive layer has a portion having a narrower width at a side of an end than at a side of a center of the solar cell along a longitudinal direction of the connection member.

4. The solar cell module according to claim 2, wherein
the adhesive layer has a portion having a narrower width at a side of an end than at a side of a center of the solar cell along a longitudinal direction of the connection member.

5. A method of manufacturing a solar cell module, comprising:
a first step in which a connection member is adhered over a light receiving surface of a solar cell with an adhesion layer therebetween; and
a second step in which a connection member is adhered over a back surface of the solar cell with an adhesion layer therebetween such that an area of the adhesive layer that adheres the connection member over the light receiving surface of the solar cell is larger than an area of the adhesive layer that adheres the connection member over the back surface of the solar cell.

6. The method of manufacturing solar cell module according to claim 5, wherein
the connection member is adhered in the first step or in the second step such that a width of the adhesive layer is narrower at a side of an end than at a side of a center of the solar cell along a longitudinal direction of the connection member.

7. The method of manufacturing solar cell module according to claim 5, wherein
an amount of the adhesive layer applied in the first step is greater than an amount of the adhesive layer applied in the second step.

8. The method of manufacturing solar cell module according to claim 6, wherein
an amount of the adhesive layer applied in the first step is greater than an amount of the adhesive layer applied in the second step.
